(19) United States
(12) Patent Application Publication
(10) Pub. No.: US 2025/0253859 A1
(43) Pub. Date: Aug. 7, 2025

(54) CURRENT SOURCE ARRAY, DIGITAL-TO-ANALOG CONVERTER AND SIGNAL CHAIN CHIP

(71) Applicant: Hangzhou Geo-chip Technology Co., Ltd., Hangzhou (CN)

(72) Inventors: Xiaoshuang ZHOU, Hangzhou (CN); Yewen Zhou, Hangzhou (CN); Dong Yang, Hangzhou (CN)

(21) Appl. No.: 19/043,950

(22) Filed: Feb. 3, 2025

(30) Foreign Application Priority Data
Feb. 2, 2024 (CN) 202410152979.8
Apr. 22, 2024 (CN) 202420844644.8

(51) Int. Cl. H03M 1/10

(52) U.S. Cl. CPC H03M 1/1014

(57) ABSTRACT

Disclosed are a current source array, a digital-to-analog converter, and a signal chain chip, the current source array comprising current sources each uniquely numbered and laid out in rows and columns, wherein in the first column, current source numbers for current source units in the first half of rows are determined from the row numbers, and the numbers of rows and columns, and current source numbers for current source units in the second half of rows are determined from the row numbers, the numbers of rows and columns, and current source numbers determined for the first half of rows; and current source numbers for current source units in each subsequent column are determined from current source numbers determined for the previous column, thereby forming an overall layout of current source array. Through the above re-layout of current sources, the overall area can be reduced, thus decreasing the gradient error.

### CROSS-REFERENCE TO RELATED PATENT APPLICATIONS

This application claims the benefits of and priorities to Chinese Patent Application No. 202410152979.8 filed on Feb. 2, 2024, and Chinese Patent Application No. 202420844644.8 filed on Apr. 22, 2024, the entire disclosures of which are incorporated by reference herein in their entirety.

### TECHNICAL FIELD

The present disclosure relates to the field of integrated circuit technology, and in particular, to a current source array, a digital-to-analog converter and a signal chain chip.

### BACKGROUND

This section is intended to provide background or context for the embodiments of the present disclosure as set forth in claims. What is described herein is not admitted as prior art merely by virtue of its inclusion in this section.

Currently, in the design and application of a digital-to-analog converter (DAC) module, the architecture and distribution of current sources constitute a vital part, with the key challenges therein involving how to overcome systematic mismatch and mitigate the effect of parasitic capacitance. Since current sources are in a form of a modular circuit that are highly dependent on layout design, their layout arrangement is crucial, directly affecting the performance metrics of the DAC module.

In the related art, with the increase in chip integration level and the accompanying change in layout area, the impact of systematic mismatch on the circuit becomes more severe, and the resulting growth in the number of devices also leads to a substantial increase in parasitic capacitance.

However, the current source arrays in the prior art typically manage to address only one issue, either systematic mismatch or parasitic capacitance, and there is a lack of a solution that not only improves systematic mismatch but also mitigate the impact of parasitic capacitance on performance.

Furthermore, the presence of even-order nonlinearity in a DAC introduces an extraneous DC offset when the DAC outputs an AC signal. Upon up-conversion by the transmitter, the DC offset causes an extraneous local oscillator (LO) component, resulting in higher LO Leakage at the RF output end. Moreover, the DC component caused due to the even-order nonlinearity of the DAC varies with the frequency and amplitude of the output signal. As a result, such DC component cannot be eliminated through static DC compensation during the calibration process. Therefore, it is needed to fundamentally suppress the even-order nonlinearity of the DAC.

### SUMMARY

The embodiments of the present disclosure at least propose a current source array, a digital-to-analog converter (DAC), and a signal chain chip that aim to mitigate the performance impact caused by both systematic mismatch and parasitic capacitance, thereby improving practicality and applicability.

The embodiments of the present disclosure also propose a DAC circuit, a transmitter, and a transceiver that aim to suppress even-order nonlinearity.

In the first aspect, the embodiments of the present disclosure provides a current source array including current sources each uniquely numbered and laid out in rows and columns, the number of the columns being equal to the total number of the current sources, and the number of the rows being equal to the total number of current source units of each current source, where the rows of the current source array include first target rows in a first half of the rows and second target rows in a second half of the rows; in the first column of the columns, a current source unit arranged in each first target row is from a current source having the current source number determined based on the row number of said each first target row, and the number of the rows and the number of columns of the current source array, and a current source unit arranged in each second target row is from a current source having the current source number determined based on the row number of said each second target row, the number of the rows and the number of the columns of the current source array, and current source numbers determined for the first target rows; and for each column except for the first column, current source units arranged in said each column are from respective current sources having respective current source numbers determined based on current source numbers determined for a previous column of said each column, thereby forming an overall layout of the current source array.

In a possible embodiment, determination of the current source number of the current source for the current source unit to be arranged in said each first target row based on the row number of said each first target row, and the number of the rows and the number of columns of the current source array is implemented by:
determining the current source number for said each first target row based on a division of the row number of said each first target row by 2 and a ratio between the number of the columns and the number of the rows of the current source array.

In a possible embodiment, the current source number, denoted as 1, for said each first target row is determined as:

$${I}_{i} = \{ \begin{matrix}( i / 2 ) \times ( 2 \times M / N + 1 ) , & i = 1 , 3 , 5 \\ ( M + 1 ) - ( i / 2 ) \times ( 2 \times M / N ) , & i = 2 , 4 , 6\end{matrix} ;$$

where M and N respectively represent the number of the columns and the number of the rows of the current source array, i represents the row number of said each first target row, and i≤N/2.

In a possible embodiment, determination of the current source number of the current source for the current source unit to be arranged in said each second target row based on the row number of said each second target row, the number of the rows and the number of the columns of the current source array, and current source numbers determined for the first target rows is implemented by:
determining a difference, denoted as X, between the number of the rows and the row number of said each second target row;
searching current source numbers, denoted as Iᵢ, determined for the first target rows to find the current source number, denoted as Iₓ, determined for a row corresponding to the difference X; and
determining the current source number for said each second target row based on the current source number, denoted as Iₓ, found.

In a possible embodiment, the current source number, denoted as Iⱼ, for said each second target row is determined as:

$${I}_{j} = ( M + 1 ) - {I}_{( X + 1 )} ; X = M - j ;$$

where M represents the number of the columns of the current source array, j represents the row number of said each second target row, and j>N/2.

In a possible embodiment, determination of the current source numbers of the current sources for the current source units to be arranged in said each column based on the current source numbers determined for the previous column of said each column is implemented by:
for each third target row in said each column, searching the current source numbers determined for the previous column to find a current source number corresponding to said each third target row, and determining the current source number for said each third target row based on the current source number found.

In a possible embodiment, searching the current source numbers determined for the previous column to find a current source number corresponding to said each third target row, and determining the current source number for said each third target row based on the current source number found is implemented by:
for the first row of said each column, searching the current source numbers determined for the previous column to find the current source number determined for a row corresponding to the row number of the first row plus 1, and determining the current source number for the first row by adding 1 to the current source number found;
for the second row of said each column, searching the current source numbers determined for the previous column to find the current source number determined for a row corresponding to the row number of the second row minus 1, and determining the current source number for the second row by adding 1 to the current source number found;
for the third row of said each column, searching the current source numbers determined for the previous column to find the current source number determined for a row corresponding to the row number of the third row plus 1, and determining the current source number for the third row by subtracting 1 from the current source number found; and
for the fourth row of said each column, searching the current source numbers determined for the previous column to find the current source number determined for a row corresponding to the row number of the fourth row minus 1, and determining the current source number for the fourth row by subtracting 1 from the current source number found.

In a possible embodiment, the specific implementation is determining the current source numbers for other rows in said each column based on the same patterns as the first to fourth rows in said each column.

In a possible embodiment, the current source units included in the current sources are sequentially labeled and the sum of current source numbers determined for each of the columns is equal.

In the second aspect, the present disclosure also provides a DAC including the current source array according to the first aspect and any one of its various embodiments.

In the third aspect, the present disclosure also provides a signal chain chip including the current source array according to the first aspect and any one of its various embodiments.

According to the above-mentioned current source array, DAC and signal chain chip, the current source array includes current sources each uniquely numbered and laid out in rows and columns, with the number of the columns being equal to the total number of the current sources, and the number of the rows being equal to the total number of current source units of each current source, where current source numbers for current source unit layout in the first and second halves of the rows in the first column of the current source array are determined in turn and then current source numbers for current source unit layout in each of the subsequent columns are determined based on current source numbers determined for the previous column, thereby forming an overall layout of the current source array. Through the re-layout of current sources as above, the overall area of the current source array can be reduced, leading to a decrease in gradient error, thus not only the problems caused by systematic mismatch are mitigated significantly, but also negative impacts of parasitic capacitance on the performance of the current sources are minimized as much as possible, resulting in improvements in both practicality and applicability.

In the fourth aspect, a DAC circuit for suppressing even-order nonlinearity is provided, including a current-mode DAC that includes a plurality of paired current source circuits and switch circuits, where for each pair of current source circuit and switch circuit, a lateral shielding circuit is provided between the current output line of the current source circuit and the data input line of the switch circuit.

In a possible embodiment, a ground line is provided between the current output line and the data input line as the lateral shielding circuit.

In a possible embodiment, the current-mode DAC is configured to suppress the frequency-dependent even-order nonlinearity.

In a possible embodiment, the DAC circuit further includes an automatic calibration device configured to perform DC component compensation during automatic calibration to eliminate an influence of transmitter local oscillator leakage (LOL) for suppressing the frequency-independent even-order nonlinearity.

In the fifth aspect, a transmitter is provided, which includes the DAC circuit according to the fourth aspect.

In a sixth aspect, a transceiver is provided, which includes the DAC circuit according to the fourth aspect.

The DAC circuit, transmitter and transceiver described above can significantly suppress the DAC even-order nonlinearity, thereby significantly improving the signal quality of the transmitter and the transceiver.

Other advantages of the present disclosure will be explained in more detail with the following description and drawings.

It should be understood that the above description is a summary of the technical solutions of the present disclosure only for the purpose of facilitating a better understanding of the technical means of the present disclosure so that the disclosure can be implemented according to the description in the specification. Specific embodiments of the present disclosure are given below to render the above and other objects, features and advantages of the present disclosure more clear.

### BRIEF DESCRIPTION OF THE DRAWINGS

In order to more clearly illustrate the technical solutions of the embodiments of the present disclosure, the drawings referred to in the embodiments will be briefly introduced below. The drawings herein are incorporated into the specification and constitute a part of the specification. These drawings show embodiments that conform to the present disclosure and are used together with the specification to illustrate the technical solution of the present disclosure. It should be understood that the drawings only show certain embodiments of the present disclosure and are not intended to be limitations to the scope of protection. For a person of ordinary skill in the art, other relevant drawings can also be obtained based on these drawings without creative effort. Moreover, the same reference characters are used throughout the drawings to represent the same components. In the drawings:

FIG. 1 shows a flow chart for determining the current source layout of the second half of rows in the first column in a current source array according to an embodiment of the present disclosure;

FIG. 2 shows an example diagram of a current source array according to an embodiment of the present disclosure;

FIG. 3 shows a flow chart for determining the current source layout of the second column in a current source array according to an embodiment of the present disclosure;

FIG. 4 shows a static performance curve of a current source array according to an embodiment of the present disclosure;

FIG. 5 shows a performance curve of a current source array according to an embodiment of the present disclosure in actual application;

FIG. 6 shows a schematic diagram of the structure of a signal chain chip according to an embodiment of the present disclosure;

FIG. 7 is an architecture of a current-mode DAC in the prior art;

FIG. 8 is a DAC circuit according to an embodiment of the present disclosure;

FIG. 9 is a comparative effect diagram of the DAC circuit according to an embodiment of the present disclosure for suppressing even-order nonlinearity.

### DETAILED DESCRIPTION

The exemplary embodiments of the present disclosure will be described in more detail below with reference to the drawings. Although the exemplary embodiments of the present disclosure are shown in the drawings, it should be understood that the present disclosure can be implemented in various forms and should not be limited by the embodiments described herein. Rather, these embodiments are provided to facilitate more thorough understanding of the present disclosure, so that the scope of the disclosure could be fully conveyed to a person of ordinary skill in the art.

In the description of the embodiments of the present disclosure, it should be understood that terms such as “including” or “having” are intended to indicate the presence of features, numbers, steps, behaviors, components, parts, or combinations thereof disclosed in this specification, and are not intended to exclude the possibility of the presence of one or more other features, numbers, steps, behaviors, components, parts, or combinations thereof.

Unless otherwise specified, “/” refers to “or”. For example, A/B may indicate A or B. In this specification, the term “and/or” merely describes the association relationship between the associated objects and indicates that there may be three relationships. For example, A and/or B may indicate three cases where only A exists, both A and B exist, and only B exists.

The terms such as “first” and “second” are for descriptive purposes only and are not intended to be construed as indicating or implying a relative importance or implicitly indicating the number of technical features indicated. Hence, features defined by “first” or “second” may explicitly or implicitly include one or more features. In the description of the embodiments of the present disclosure, “a plurality of” means two or more in number, unless otherwise specified.

It should also be noted that, in the absence of conflict, the embodiments and features in the embodiments of the present application can be combined with each other. The present disclosure will be described in detail with reference to the accompanying drawings and in combination with the embodiments.

In the related art, the system error of the digital-to-analog converter (DAC) is also referred to as the gradient error. The gradient error increases as the area of the current source array enlarges. Specifically, as the resolution of the DAC improves, the area of the current source array quadruples for each additional bit of accuracy. Consequently, the gradient error in the current source array becomes one of the primary factors limiting the accuracy of the DAC.

It is known that as the layout area changes due to an increase in chip integration levels, the impact of systematic mismatch on the circuit becomes more severe. Additionally, the resulting growth in the number of devices leads to a substantial increase in parasitic capacitance.

In order to at least partially solve one or more of the above problems and other potential problems, the present disclosure provides a current source array, a DAC and a signal chain chip to mitigate the negative impacts caused by both systematic mismatch and parasitic capacitance, thereby improving practicality and applicability.

To facilitate understanding of the embodiments, the current source array according to the embodiments of the present disclosure is first introduced in detail. The current source array according to the embodiments of the present disclosure mainly includes current sources each uniquely numbered and laid out in rows and columns, with the number of the columns being equal to the total number of the current sources, and the number of the rows being equal to the total number of current source units of each current source, where the rows of the current source array include first target rows in a first half of the rows and second target rows in a second half of the rows; in the first column of the columns, a current source unit arranged in each first target row is from a current source having the current source number determined based on the row number of said each first target row, and the number of the rows and the number of columns of the current source array, and a current source unit arranged in each second target row is from a current source having the current source number determined based on the row number of said each second target row, the number of the rows and the number of the columns of the current source array, and current source numbers determined for the first target rows; and for each column except for the first column, current source units arranged in said each column are from respective current sources having respective current source numbers determined based on current source numbers determined for a previous column of said each column, thereby forming an overall layout of the current source array.

In order to facilitate the understanding of the current source array according to the embodiments of the present disclosure, the application scenario of the current source array is first described in detail. The current source array herein is primarily applicable to DACs, especially high-speed DACs, such as high-speed and high-precision current steering DAC. However, the embodiments of the present disclosure are not limited thereto in scope. The current steering DAC is selected as a representative example in the following descriptions.

To address the limitation that existing solutions in the related art cannot mitigate the performance impacts caused by both systematic mismatch and parasitic capacitance, the embodiments of the present disclosure provide a current source array based on current source re-layout. The gradient error increases as the area of the current source array enlarges, especially as the resolution of DAC improves, the area of the current source array quadruples for each additional bit of accuracy. Consequently, the gradient error in the current source array becomes one of the primary factors limiting the accuracy of the DAC. Therefore, the embodiments of the present disclosure implement a current source re-layout solution that can reduce the overall area of the current source array, leading to a decrease in gradient error, thereby not only improving the systematic matching, but also minimizing the performance degradation caused by large parasitic capacitance as much as possible.

In the current source array according to the embodiments of the present disclosure, the current sources can be reasonably laid out and distributed across different rows and columns, thereby providing technical feasibility for the mitigation of gradient error. At the same time, in order to solve the gradient error in the row direction, the number of current source units of each current source is set to be equal to the number of the rows.

In addition, since the output parasitic capacitance of the current source significantly affects the dynamic performance of the high-speed DACs, such as the spur free dynamic range (SFDR). In order to reduce the output parasitic capacitance of the current source, the number of the rows should not be too large, while the number of columns is set to be equal to the number of current sources. This configuration ensures the current steering DAC is composed of current sources, the number of which is equal to the number of the columns, that is, current source units in an array of rows and columns.

Here, in order to achieve an optimized layout for the current source array, a column-by-column arrangement method may be employed. Specifically, this involves laying out all the rows in the first column before moving on to the second column, and so on, until all rows in all columns are laid out. Once the structural numbering is complete, the corresponding current source units are placed in the positions indicated by the numbers in the array to form a complete circuit, thereby achieving a current source array with superior performance.

The layout of the first column will directly influence layouts of the subsequent columns. For clarity, the layout of the first column of the current source array is first described in the embodiments of the present disclosure.

In the layout process for the first column, the layout for the first half and the second half of the rows are determined separately. For each first target row in the first half of the rows, a current source unit arranged in said each first target row is from a current source having the current source number determined based on the row number of said each first target row, and the number of the rows and the number of columns of the current source array. For each second target row in the second half of the rows, a current source unit arranged in said each second target row is from a current source having the current source number determined based on the row number of said each second target row, the number of the rows and the number of the columns of the current source array, and current source numbers determined for the first target rows.

For the sake of clarity, the term “first target row” refers to a row in the first half of the rows, while “second target row” refers to a row in the second half of the rows. For example, in a current source array with 8 rows and 64 columns, the principle of number determination is consistent across all columns. Therefore, for any column within the 64 columns, the first 4 rows are designated as the first target rows, and the last 4 rows are designated as the second target rows.

In the actual layout process for the first target rows in the first column, the current source number of the current source for the current source unit to be arranged in the first target row is determined based on a division of the row number of the first target row by 2 and the ratio between the number of columns and the number of rows of the current source array.

In order to facilitate understanding of the specific layout for the first target rows, the following will be explained in combination with formulas and corresponding examples.

For ease of explanation, M and N are respectively denoted to represent the number of columns and the number of rows of the current source array, and i represents the row number of the first target row. The current source number, denoted as Iᵢ, of the current source for said each first target row is determined as:

$${I}_{i} = \{ \begin{matrix}( i / 2 ) \times ( 2 \times M / N + 1 ) , & i = 1 , 3 , 5 \\ ( M + 1 ) - ( i / 2 ) \times ( 2 \times M / N ) , & i = 2 , 4 , 6\end{matrix} .$$

For the convenience of arrangement, it is assumed that the number M of columns can be exactly divided by the number N of rows, and M and N are both integer powers of 2. For example, for a current source array with 8 rows and 64 columns, the current source number for the third row (i.e., the odd row) is determined as I₃=(3/2)×(2×64/8+1)=17.

For another example, still for a current source array with 8 rows and 64 columns, the current source number for the second target row (i.e., the even row) is determined as I₂=(64+1)−(2/2)×(2δ4/8)=49.

It is known that for the first half of the rows in the first column, the layout for the odd rows and the even rows may be determined separately to achieve a further optimized layout strategy in the embodiments of the present disclosure.

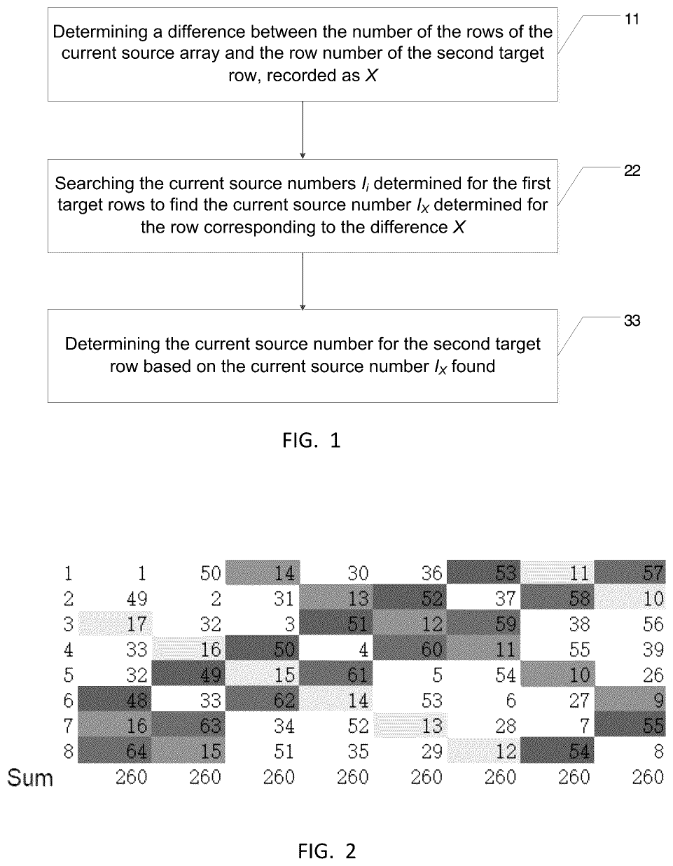

In actual layout process for the second target rows in the first column, the corresponding current source numbers may be specifically determined based on the current source numbers determined for the first half of the rows, that is, the layout for the second half of the rows of the first target row can refer to the layout strategy for the first half of the rows, which can be specifically implemented by the following steps, with reference to FIG. 1.

S11: a difference X between the number of the rows of the current source array and the row number of the second target row is determined.

S12: the current source numbers/determined for the first target rows are searched for the current source number Iₓ determined for a row corresponding to the difference X.

S13: the current source number for the second target row is determined based on the current source number Iₓ found.

Here, in order to facilitate understanding of the specific layout method for the second target rows, the following will be explained in combination with formulas and corresponding examples.

Similarly, M and N here are also respectively denoted to represent the number of columns and rows of the current source array, j represents the row number of the second target row, and the current source number I; of the current source unit to be arranged in the second target row is determined according to the following formula:

$${I}_{j} = ( M + 1 ) - {I}_{( X + 1 )} ; X = M - j .$$

Here, taking an 8-row and 64-column current source array as an example, the current source number for the 7th row in the first column is determined as

$${I}_{7} = ( 64 + 1 ) - {I}_{( 87 + t )} = 65 - {I}_{2} = 65 - 49 = 16 .$$

It should be noted that the multiple current source units included in the multiple current sources in the embodiments of the present disclosure are labeled in sequence. Taking the current steering DAC as an example, the DAC is composed of M current sources (corresponding to the number of columns of the current source array), and each current source is composed of N current source units (corresponding to the number of rows of the current source array), which are respectively labeled as Iₘ₁˜I_{mN}, where m is any integer from 0 to (M −1). The current source numbers corresponding to the respective labels of the current source units of each current source may be determined according to the order of arrangement of the current source units.

In order to further address the gradient error in the column direction, the sum of current source numbers determined for each of the columns is equal to the same constant, referring to FIG. 2.

Based on the above description of the first and second halves of rows in the first column, the current source numbers for the entire first column can be determined.

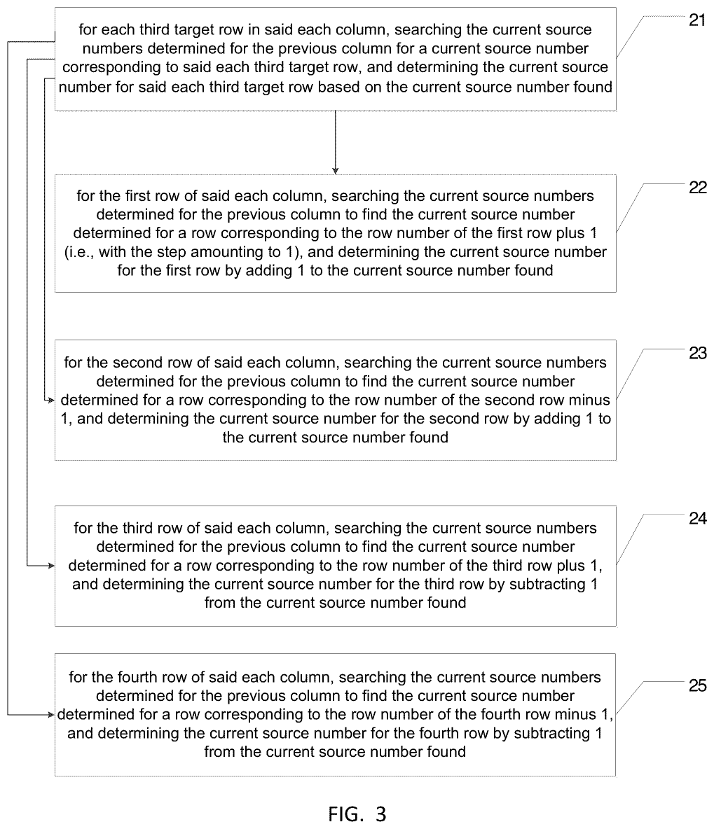

Based on the current source numbers determined for the first column, the current source numbers for the layout of the second column can be determined. Similarly, based on the current source numbers determined for the second column, the current source numbers for the layout of the third column can be determined, and so on. As shown in FIG. 3, the specific implementation may be as follows.

S21: for each third target row in said each column, the current source numbers determined for the previous column are searched for a current source number corresponding to said each third target row, and the current source number for said each third target row is determined based on the current source number found.

S22: for the first row of said each column, the current source numbers determined for the previous column are searched for the current source number determined for a row corresponding to the row number of the first row plus 1 (i.e., with the step amounting to 1), and the current source number for the first row is determined by adding 1 to the current source number found.

S23: for the second row of said each column, the current source numbers determined for the previous column are searched for the current source number determined for a row corresponding to the row number of the second row minus 1, and the current source number for the second row is determined by adding 1 to the current source number found.

S24: for the third row of said each column, the current source numbers determined for the previous column are searched for the current source number determined for a row corresponding to the row number of the third row plus 1, and the current source number for the third row is determined by subtracting 1 from the current source number found.

S25: for the fourth row of said each column, the current source numbers determined for the previous column are searched for the current source number determined for a row corresponding to the row number of the fourth row minus 1, and the current source number for the fourth row is determined by subtracting 1 from the current source number found.

Then, the current source numbers for other rows in said each column are determined based on the same patterns as the first to fourth rows in said each column.

It should be noted that the third target row here is only used to indicate a row of a column after the previous column, and is not limited to the first row, the last row, the middle row, etc.

In the specific implementation, after current source numbers for the first column is determined, the current source numbers for the next column are determined based on the row number of the previous column according to the following rules, namely:
a) for the first row, the row number is increased by 1, and the current source number is increased by 1;
b) for the second row, the row number is reduced by 1, and the current source number is increased by 1;
c) for the third row, the row number is increased by 1, and the current source number is reduced by 1;
d) for the fourth row, the row number is reduced by 1, and the current source number is reduced by 1;
e) for the fifth row, the rule for the first row is reused, and if the row number and the current source number after arrangement reaches the maximum or minimum value, then renumbering is performed from the minimum and the maximum value.

In order to further illustrate the layout strategy according to the embodiments of the present disclosure, two specific examples will be described below.

First, taking the first 8 columns in the array of 8 rows and 64 columns as an example, after arrangement according to the above rules, the sum of current source numbers in each column is 260. The specific arrangement is shown in Table 1 below (corresponding to FIG. 1).

TABLE 1

| | Column | Column | Column | Column | Column | Column | Column | Column |
|---|---|---|---|---|---|---|---|---|
| | 1 | 2 | 3 | 4 | 5 | 6 | 7 | 8 |
| Row 1 | 1 | 50 | 14 | 30 | 36 | 53 | 11 | 57 |
| Row 2 | 49 | 2 | 31 | 13 | 52 | 37 | 58 | 10 |
| Row 3 | 17 | 32 | 3 | 51 | 12 | 59 | 38 | 56 |
| Row 4 | 33 | 16 | 50 | 4 | 60 | 11 | 55 | 39 |
| Row 5 | 32 | 49 | 15 | 61 | 5 | 54 | 10 | 26 |
| Row 6 | 48 | 33 | 62 | 14 | 53 | 6 | 27 | 9 |
| Row 7 | 16 | 63 | 34 | 52 | 13 | 28 | 7 | 55 |
| Row 8 | 64 | 15 | 51 | 35 | 29 | 12 | 54 | 8 |
| Sum | 260 | 260 | 260 | 260 | 260 | 260 | 260 | 260 |

Secondly, taking the first 8 columns in an array of 4 rows and 64 columns as an example, after arrangement according to the above rules, the sum of current source numbers in each column is 130. The specific arrangement is shown in Table 2 below.

TABLE 2

| | Column | Column | Column | Column | Column | Column | Column | Column |
|---|---|---|---|---|---|---|---|---|
| | 1 | 2 | 3 | 4 | 5 | 6 | 7 | 8 |
| Row 1 | 1 | 34 | 30 | 61 | 5 | 38 | 26 | 57 |
| Row 2 | 33 | 2 | 62 | 29 | 37 | 6 | 58 | 25 |
| Row 3 | 32 | 63 | 3 | 36 | 28 | 59 | 7 | 40 |
| Row 4 | 64 | 31 | 35 | 4 | 60 | 27 | 39 | 8 |
| Sum | 130 | 130 | 130 | 130 | 130 | 130 | 130 | 130 |

It can be seen from the above that after the current sources are laid out according to the layout strategy according to the embodiment of the present disclosure, the current source units of each current source are distributed in different rows and columns, which can effectively reduce the systematic (such as gradient) error. At the same time, the number of rows is controlled to a smaller value, which effectively reduces the parasitic capacitance of the current source and improves the dynamic performance of the DAC, such as the SFDR . . .

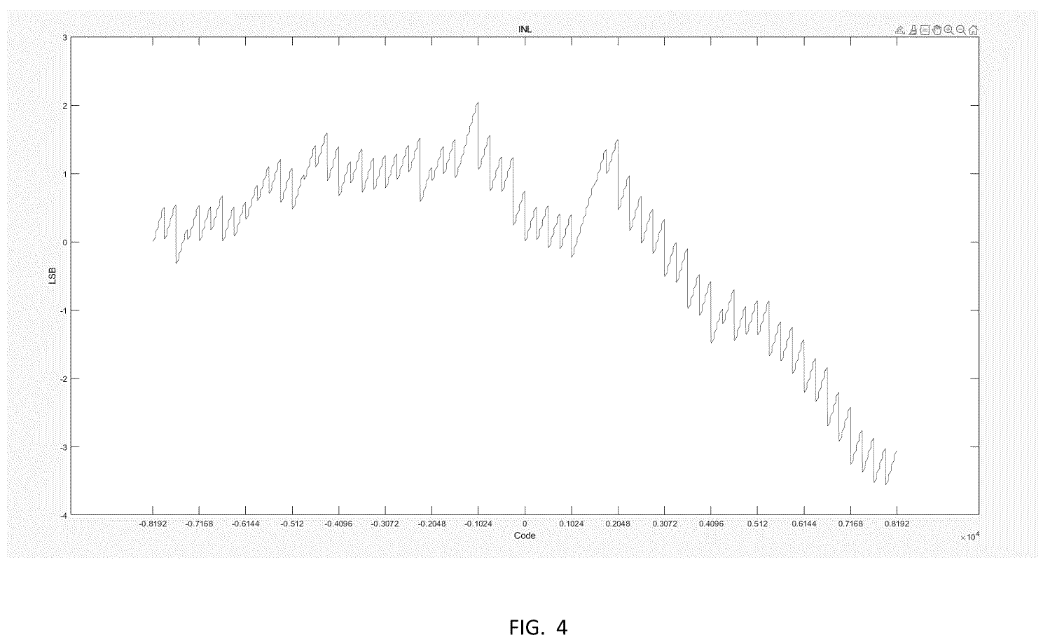

In FIG. 4, the static performance curve of the current source array according to the embodiment of the present disclosure is shown. The horizontal axis in the performance curve is used to indicate the value range, and the vertical axis is used to characterize the least significant bit (LSB) of the performance parameter of the system matching. It can be seen from the above static performance curve that the embodiments of the present disclosure can significantly reduce the adverse effects of parasitic capacitance while ensuring the system matching.

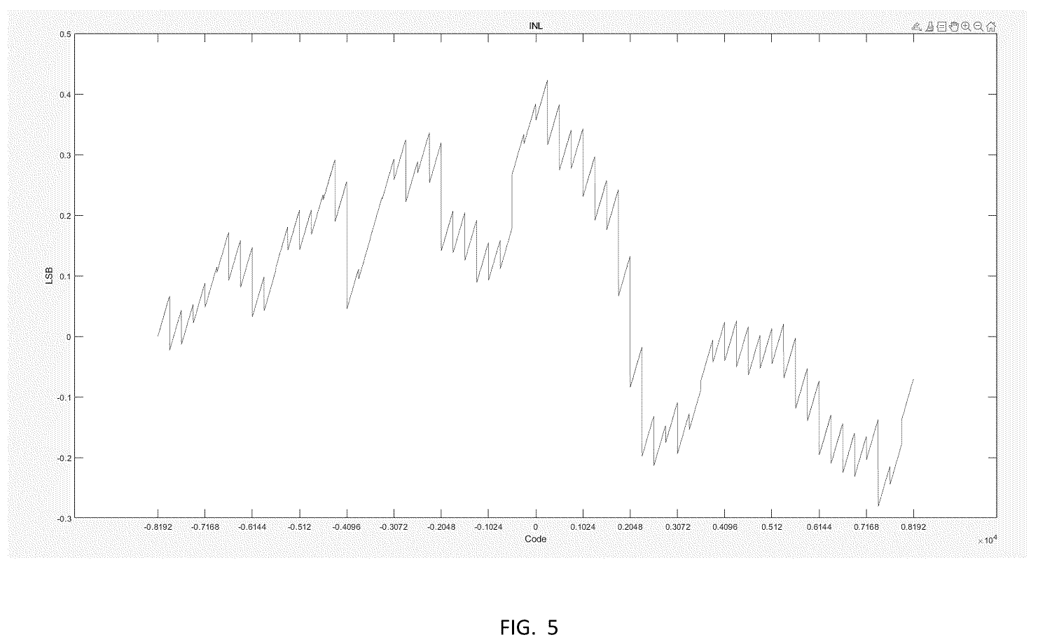

FIG. 5 shows the performance curve of the current source array according to the embodiments of the present disclosure in the actual application process (i.e., MATLAB, INL integral nonlinearity curve), from which it can be seen that in actual applications, good system performance is also achieved, thus providing wider practicality and applicability.

Based on the current source array according to the embodiment of the present disclosure, the embodiment of the present disclosure also provides a DAC, which can provide a more stable current output mode through the current source array, thus further improving the conversion performance.

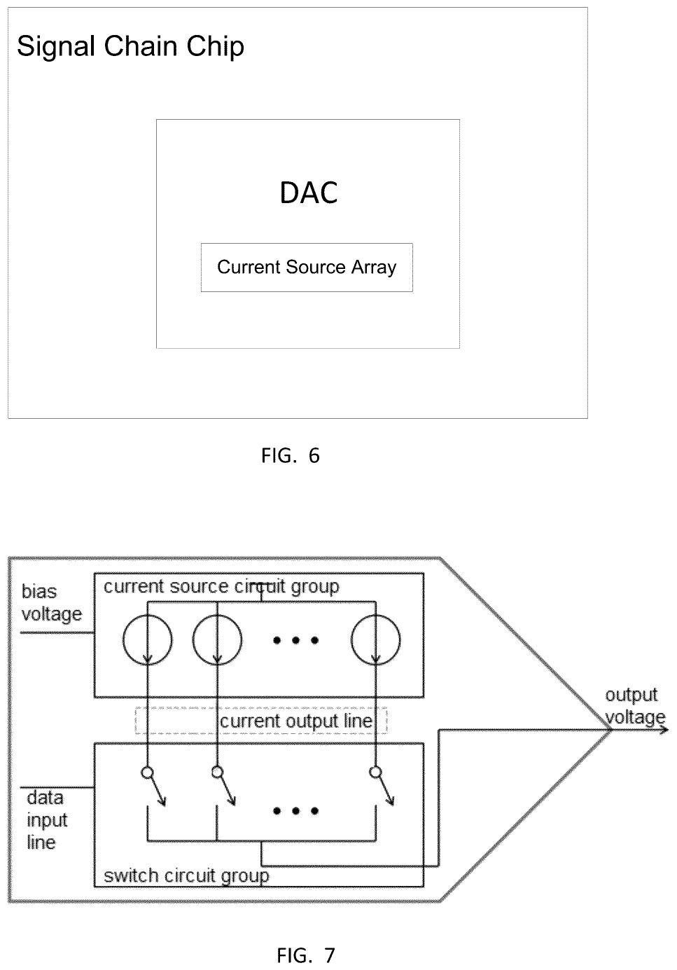

In addition, referring to FIG. 6, the embodiment of the present disclosure also provides a signal chain chip including the above current source array, which achieves improved processing performance.

FIG. 7 shows a schematic diagram of the architecture of a current-mode DAC.

Referring to FIG. 7, the current-mode DAC includes a current source circuit group and a switch circuit group, each including multiple current source circuits and switch circuits arranged in parallel, where a bias voltage is applied to the current source circuit group as a power-on voltage, and a current output line is provided at the output side of the current source circuit group; a level pulse signal (0 or 1) is input to the switch circuit group through a data input line to control the ON/OFF of each switch.

The present disclosure studies the current-mode DAC architecture shown in FIG. 7, and accurately confirms that the even-order nonlinearity of the DAC is mainly derived from the capacitive coupling between the current output line (CURRENT_OUT) of the current source circuit group and the data input line (DATA_IN) of the switch circuit group through the control test after the layout parasitic extraction and the actual measurement verification of the chip.

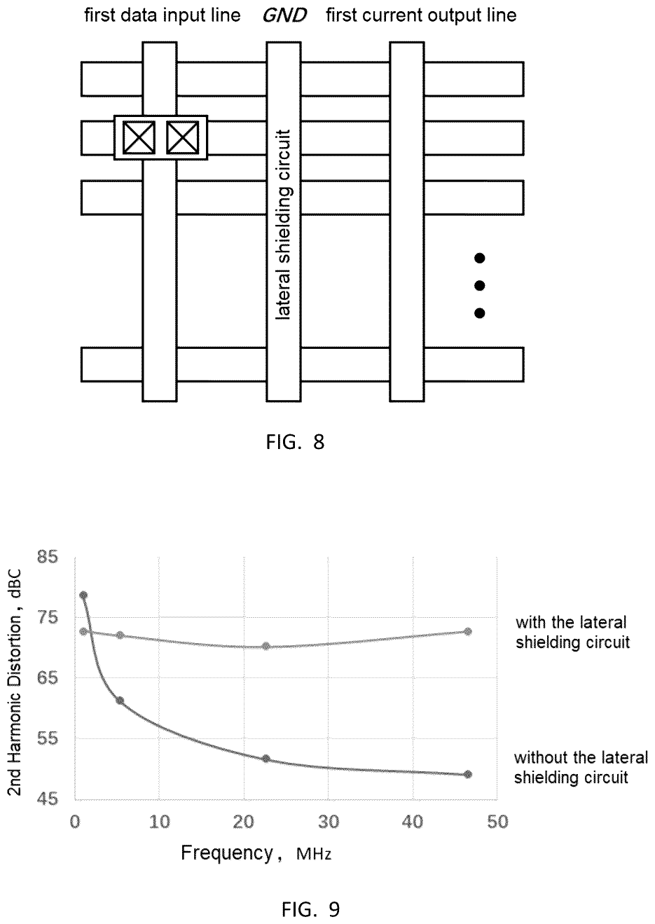

FIG. 8 shows a DAC circuit for suppressing even-order nonlinearity according to embodiments of the present disclosure.

In order to reduce the capacitive coupling between the lines, in the embodiments of the present disclosure, a lateral shielding circuit is added between each pair of current output line (CURRENT_OUT) and data input line (DATA_IN) of the current source circuit group and the switch circuit group to significantly reduce the capacitive coupling between the current output lines (CURRENT_OUT) and the data input lines (DATA_IN), thereby reducing the even-order nonlinearity of the DAC output. Specifically, in the actual circuit layout design, the input/output routing methods are intricate. In the embodiment of the present disclosure, a lateral shielding circuit is added between the current output line of the current source circuit and the data input line that controls the switch for each pair of current source and switch connected in serial.

For example, assuming that the leftmost current source in FIG. 7 is the first current source and the leftmost switch is the first switch, referring to FIG. 8, the lateral shielding circuit is provided between the first data input line connected to the first switch and the first current output line at the output side of the first current source to reduce the capacitive coupling therebetween.

Preferably, in the embodiments of the present disclosure, a ground line (GND) is added between each pair of CURRENT_OUT and DATA_IN lines. It can be understood that by providing the ground line, the capacitive coupling can be reduced at a low cost.

FIG. 9 shows a diagram of the effect of the DAC circuit of the embodiments of the present disclosure on suppressing even-order nonlinearity, and the comparison shows the variation of the output second harmonic distortion (dBC) of the current-mode DAC with the output frequency (MHZ) before and after the addition of lateral shielding. Through the simulation comparison after parasitic extraction, it can be seen that after adopting the layout technology for suppressing DAC even-order nonlinearity in the embodiments of the present application, the harmonic distortion caused by the DAC second-order nonlinearity is reduced by more than 20 dB.

Preferably, since the DC component caused by the DAC even-order nonlinearity varies with the frequency and amplitude of the output signal, such a DC component cannot be eliminated by static DC compensation during the calibration process, so the current-mode DAC of the present application is specifically configured to suppress the frequency-dependent DAC even-order nonlinearity.

Preferably, the DAC circuit of the embodiment of the present disclosure further includes an automatic calibration device configured to perform DC component compensation during automatic calibration to eliminate an influence of transmitter local oscillator leakage (LOL) for suppressing the frequency-independent even-order nonlinearity.

The embodiments of the present disclosure also provide a transmitter including the DAC circuit for suppressing even-order nonlinearity described in the above embodiment.

The embodiments of the present disclosure also provide a transceiver including the DAC circuit for suppressing even-order nonlinearity described in the above embodiment.

It can be understood that the DAC circuit of the above embodiment of the present disclosure can significantly suppress the DAC even-order nonlinearity. Further, suppressing the DAC even-order nonlinearity can effectively reduce the DC offset at the output of the DAC, thereby reducing the local oscillator leakage caused by the DC component at the antenna end after the transmitter up-conversion. Those skilled in the art understand that the leaked local oscillator signal will cause the quality of the transmitter signal to deteriorate and cause the vector magnitude error (EVM) to deteriorate. Therefore, suppressing the DAC even-order nonlinearity is of great significance to improving the signal quality of the transmitter or transceiver.

It should be noted that the above embodiments of the current-mode DAC can be at least partially applied to the embodiments of the current source array and the DAC including it, and vice versa. Exemplarily, the current source circuit can be used for the above-mentioned current source units respectively, for example, each current source unit is included in a current source circuit.

In the description of this specification, the description with reference to the terms “some possible embodiments”, “some embodiments”, “examples”, “specific examples”, or “some examples” means that the specific features, structures, materials or characteristics described in conjunction with the embodiment or example are included in at least one embodiment or example of the present disclosure, and the above terms do not necessarily represent the same embodiment or example. Moreover, the specific features, structures, materials or characteristics described can be combined in any one or more embodiments or examples in a suitable manner. In addition, the different embodiments or examples described in this specification and the features of different embodiments or examples can be combined and combined by a person skilled in the art without contradiction.

Regarding the method flow chart of the embodiment of the present disclosure, certain operations are described as different steps performed in a certain order. Such a flow chart is illustrative rather than restrictive. Certain steps described in this article can be grouped together and performed in a single operation, or certain steps can be divided into multiple sub-steps, and certain steps can be performed in a different order than shown in this article. The various steps shown in the flow chart can be implemented in any way by any circuit structure and/or tangible mechanism (for example, by software running on a computer device, hardware (for example, a logical function implemented by a processor or chip), etc., and/or any combination thereof).

Those skilled in the art can understand that in the method described in the above specific embodiments, the writing order of each step does not mean a strict execution order, and the specific execution order of each step should correspond to its function and possible internal logic.

Although the spirit and principle of the present disclosure have been described above with reference to several specific embodiments, it should be understood that the present disclosure is not limited to the disclosed specific embodiments, and the division of various aspects does not mean that the features in these aspects cannot be combined. The present disclosure is intended to cover various modifications and equivalent arrangements included in the spirit and scope of the attached claims.

What is claimed is:

1. A current source array, comprising current sources each uniquely numbered and laid out in rows and columns, with the number of the columns being equal to a total number of the current sources, and the number of the rows being equal to a total number of current source units of each current source,
wherein the rows of the current source array comprise first target rows in a first half of the rows and second target rows in a second half of the rows;
in the first column of the columns, a current source unit arranged in each first target row is from a current source having the current source number determined based on the row number of said each first target row, and the number of the rows and the number of columns of the current source array; and a current source unit arranged in each second target row is from a current source having the current source number determined based on the row number of said each second target row, the number of the rows and the number of the columns of the current source array, and current source numbers determined for the first target rows; and
for each column except for the first column, current source units arranged in said each column are from respective current sources having respective current source numbers determined based on current source numbers determined for a previous column of said each column, thereby forming an overall layout of the current source array.

2. The current source array according to claim 1, wherein determination of the current source number of the current source for the current source unit to be arranged in said each first target row based on the row number of said each first target row, and the number of the rows and the number of columns of the current source array is implemented by:
determining the current source number for said each first target row based on a division of the row number of said each first target row by 2 and a ratio between the number of the columns and the number of the rows of the current source array.

3. The current source array according to claim 2, wherein the current source number, denoted as Iᵢ, for said each first target row is determined as:
$${I}_{i} = \{ \begin{matrix}( i / 2 ) \times ( 2 \times M / N + 1 ) , & i = 1 , 3 , 5 \\ ( M + 1 ) - ( i / 2 ) \times ( 2 \times M / N ) , & i = 2 , 4 , 6\end{matrix} ;$$
wherein M and N respectively represent the number of the columns and the number of the rows of the current source array, i represents the row number of said each first target row, and i≤N/2.

4. The current source array according to claim 1, wherein determination of the current source number of the current source for the current source unit to be arranged in said each second target row based on the row number of said each second target row, the number of the rows and the number of the columns of the current source array, and current source numbers determined for the first target rows is implemented by:
determining a difference, denoted as X, between the number of the rows and the row number of said each second target row;
searching current source numbers, denoted as Iᵢ, determined for the first target rows to find the current source number, denoted as Iₓ, determined for a row corresponding to the difference X; and
determining the current source number for said each second target row based on the current source number, denoted as Iₓ, found.

5. The current source array according to claim 4, wherein the current source number, denoted as Iⱼ, for said each second target row is determined as:
$${I}_{j} = ( M + 1 ) - {I}_{( X + 1 )} ; X = M - j ;$$
wherein M represents the number of the columns of the current source array, j represents the row number of said each second target row, and j>N/2.

6. The current source array according to claim 1, determination of the current source numbers of the current sources for the current source units to be arranged in said each column based on the current source numbers determined for the previous column of said each column is implemented by:
for each third target row in said each column, searching the current source numbers determined for the previous column to find a current source number corresponding to said each third target row, and determining the current source number for said each third target row based on the current source number found.

7. The current source array according to claim 6, wherein searching the current source numbers determined for the previous column to find a current source number corresponding to said each third target row, and determining the current source number for said each third target row based on the current source number found is implemented by:
for the first row of said each column, searching the current source numbers determined for the previous column to find the current source number determined for a row corresponding to the row number of the first row plus 1, and determining the current source number for the first row by adding 1 to the current source number found;
for the second row of said each column, searching the current source numbers determined for the previous column to find the current source number determined for a row corresponding to the row number of the second row minus 1, and determining the current source number for the second row by adding 1 to the current source number found;
for the third row of said each column, searching the current source numbers determined for the previous column to find the current source number determined for a row corresponding to the row number of the third row plus 1, and determining the current source number for the third row by subtracting 1 from the current source number found; and
for the fourth row of said each column, searching the current source numbers determined for the previous column to find the current source number determined for a row corresponding to the row number of the fourth row minus 1, and determining the current source number for the fourth row by subtracting 1 from the current source number found.

8. The current source array according to claim 7, wherein the current source numbers for other rows in said each column are determined based on the same patterns as the first to fourth rows in said each column.

9. The current source array according to claim 1, wherein the current source units comprised in the current sources are sequentially labeled and the sum of current source numbers determined for each of the columns is equal.

10. A digital-to-analog converter comprising the current source array according to claim 1.

11. The digital-to-analog converter according to claim 10, further comprising a plurality of paired current source circuits and switch circuits configured respectively for the current source units,
wherein for each pair of a current source circuit and a switch circuit, a lateral shielding circuit is provided between a current output line of the current source circuit and a data input line of the switch circuit to suppress even-order nonlinearity.

12. The digital-to-analog converter according to claim 11, wherein a ground line is provided between the current output line and the data input line as the lateral shielding circuit.

13. The digital-to-analog converter according to claim 11, wherein the digital-to-analog converter is configured to suppress frequency-dependent even-order nonlinearity.

14. The digital-to-analog converter according to claim 11, further comprising an automatic calibration device configured to perform direct current (DC) component compensation during automatic calibration to eliminate an influence of transmitter local oscillator leakage (LOL) for suppressing frequency-independent even-order nonlinearity.
